(19) United States
(12) Patent Application Publication
(10) Pub. No.: US 2025/0392276 A1
(43) Pub. Date: Dec. 25, 2025

(54) DECISION FEEDBACK EQUALIZER WITH VARIABLE GAIN AMPLIFIER CALIBRATION

(71) Applicant: Micron Technology, Inc., Boise, ID (US)

(72) Inventor: Jinha Hwang, Boise, ID (US)

(21) Appl. No.: 19/065,401

(22) Filed: Feb. 27, 2025

Related U.S. Application Data
(60) Provisional application No. 63/662,218, filed on Jun. 20, 2024.

(51) Int. Cl. H03G 3/30; H03F 3/19; H04L 25/03

(52) U.S. Cl. CPC H03G 3/3036; H03F 3/19; H04L 25/03057; H03G 2201/103

(57) ABSTRACT

A device, includes an amplifying device that when in operation transmits a data signal and a reference signal to a decision feedback equalizer (DFE) circuit. The amplifying device includes a variable gain amplifier (VGA) that when in operation generates the reference signal as having a predetermined gain relative to a received input signal and a continuous-time linear equalizer (CTLE) that operates to mitigate inter-symbol interference (ISI) on the data signal from a data stream comprising the data signal. The device also includes compensation circuitry coupled to the amplifying device, wherein the compensation circuitry when in operation calibrates the amplifying device by adjusting a voltage level of the data signal based upon a data strobe (DQS) signal.

### CROSS REFERENCE TO RELATED APPLICATIONS

This application is a Non-Provisional application claiming priority to U.S. Provisional Patent Application No. 63/662,218, entitled “DECISION FEEDBACK EQUALIZER WITH VARIABLE GAIN AMPLIFIER”, filed Jun. 20, 2024, which is herein incorporated by reference.

### BACKGROUND

### Field of the Present Disclosure

Embodiments of the present disclosure relate generally to the field of input buffers and Decision Feedback Equalizers (DFEs) for memory devices. More specifically, embodiments of the present disclosure relate to reducing noise of signals provided to the DFE.

### Description of Related Art

The operational rate of memory devices, including the data rate of a memory device, has been increasing over time. As a side effect of the increase in speed of a memory device, data errors due to distortion may increase. For example, inter-symbol interference between transmitted data whereby previously received data influences the currently received data may occur (e.g., previously received data affects and interferes with subsequently received data). One manner to correct for this interference is through the use of a decision feedback equalizer (DFE) circuit, which may be programmed to offset (i.e., undo or mitigate) the effect of the channel on the transmitted data.

To insure the proper functioning of the DFE circuit, reliable input signals should be available. Indeed, noise from input signals to the DFE circuit can lead to unreliable results and operation of the DFE circuit. Accordingly, it may be desirable to provide improved inputs to the DFE circuit to allow for increases in the operational efficiency of the DFE circuit.

Embodiments of the present disclosure may be directed to one or more of the problems set forth above.

### BRIEF DESCRIPTION OF DRAWINGS

Various aspects of this disclosure may better be understood upon reading the following detailed description and upon reference to the drawings in which:

FIG. 1 is a simplified block diagram illustrating certain features of a memory device, according to an embodiment of the present disclosure;

FIG. 2 is a block diagram illustrating a data transceiver of the I/O interface of FIG. 1, according to an embodiment of the present disclosure;

FIG. 3 illustrates a block diagram of an embodiment of the data transceiver of FIG. 2, according to an embodiment of the present disclosure;

FIG. 4 illustrates a high level diagram of a Decision Feedback Equalizer of the data transceiver of FIG. 2, according to an embodiment of the present disclosure;

FIG. 5 illustrates a block diagram of a first embodiment of the DFE of FIG. 4, according to an embodiment of the present disclosure;

FIG. 6 illustrates a block diagram of a second embodiment the DFE of FIG. 4, according to an embodiment of the present disclosure;

FIG. 7 illustrates a first embodiment of the variable gain amplifier (VGA) utilized in conjunction with the first embodiment of the DFE of FIG. 5 or the second embodiment of the DFE of FIG. 6, according to an embodiment of the present disclosure;

FIG. 8 illustrates examples of voltage graphs when different references voltages are provided to the VGA of FIG. 7, according to an embodiment of the present disclosure;

FIG. 9 illustrates a first embodiment of calibration circuitry utilized in conjunction with the VGA of FIG. 7, according to an embodiment of the present disclosure; and

FIG. 10 illustrates examples of voltage graphs generated with and without the utilization of calibration circuitry of FIG. 9, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Using a decision feedback equalizer (DFE) of a memory device to perform distortion correction techniques may be valuable, for example, to correctly compensate for distortions in the received data of the memory device. This insures that accurate values are being stored in the memory of the memory device. The DFE may use previous bit data to create corrective values to compensate for distortion resulting from previously received data bit(s). For example, the most recent previous bit may have more of a distortion effect on the current bit than a bit transmitted several data points before, causing the corrective values to be different between the two bits. With these levels to correct for, the DFE may operate to correct the distortion of the transmitted bit.

Reference voltages are utilized in generation of signals supplied to the DFE. However, in some embodiments, these reference voltages may be varied. Varying these reference voltages can lead to increased noise from DC margin variations, which increase the difficulty in setting desired (e.g., optimum) DC-operating points (e.g., the DC common mode voltage) of an amplifying device supplying signals to the DFE. Therefore, in some embodiments, DQ (e.g., data I/O signal) compensation of the amplifying device can be achieved by DC-extraction of an operating point from a DQS (e.g., data strobe signals) pin instead of from a DQ pin. That is, while the DC-common mode value of a DQ signal is affected by changes to the reference voltage, the DC-common mode value of DQS is not affected or changes by to the reference voltage provided to the amplifying device. Thus, as discussed below, systems and techniques for DC-extraction from a DQS pin instead of from the DQ pin can be implemented to overcome the above noted challenges and to provide calibration to an amplifying device that supplies signals to the DFE.

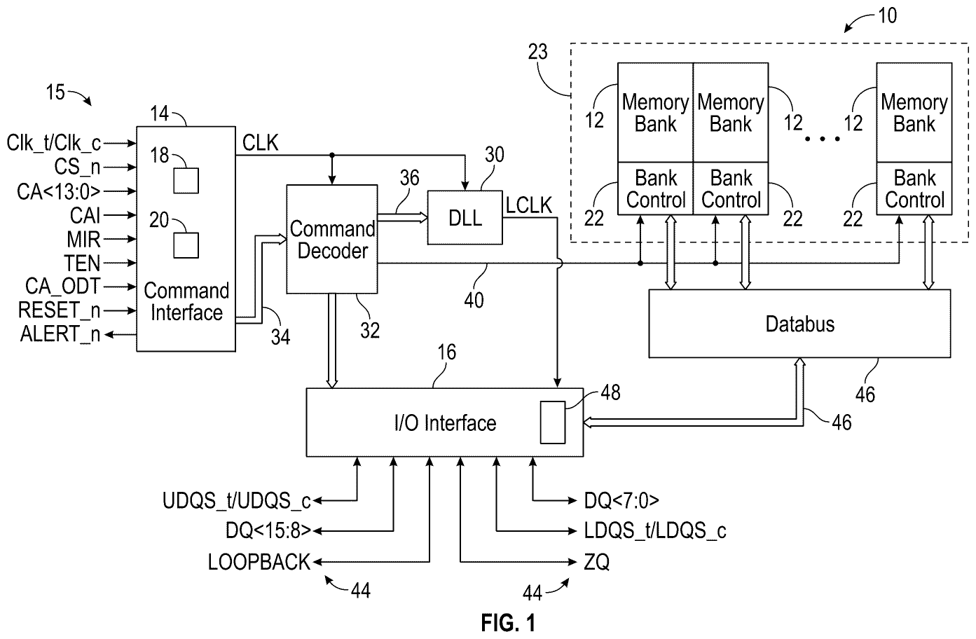

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous dynamic random access memory (DDR5 SDRAM or DDR5) device. Various features of DDR5 SDRAM allow for reduced power consumption, more bandwidth and more storage capacity compared to prior generations of DDR SDRAM. However, more generally, the memory device 10 may be a random access memory (RAM) device, a dynamic RAM (DRAM) device, a static RAM (SRAM) device (including a double data rate SRAM device), flash memory, and/or a phase change memory (PCM) device and/or other chalcogenide-based memory, such as self-selecting memories (SSM), a double data rate type four synchronous dynamic random access memory (DDR4 SDRAM) device, a low power double data rate type four synchronous dynamic random access memory (LPDDR4 SDRAM), a low power double data rate type five synchronous dynamic random access memory (LPDDR5 SDRAM) device, a data rate type six synchronous dynamic random access memory (DDR6 SDRAM or DDR6), or another type of device.

The memory device 10, may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 GB DDR5 SDRAM, the memory chip may include 32 memory banks 12, arranged into 8 bank groups, each bank group including 4 memory banks, for instance. Various other configurations, organization and sizes of the memory banks 12 on the memory device 10 may be utilized depending on the application and design of the overall system.

The memory device 10 may include a command interface 14 and an input/output (I/O) interface 16 configured to exchange (e.g., receive and transmit) signals with external devices. The command interface 14 is configured to provide a number of signals (e.g., signals 15) from an external device (not shown), such as a processor or controller (e.g., present in a host device coupled to the memory device 10). The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command address input circuit 20, for instance, to ensure proper handling of the signals 15. The command interface 14 may receive one or more clock signals from an external device. Generally, double data rate (DDR) memory utilizes a differential pair of system clock signals, referred to herein as the true clock signal (Clk_t) and the complementary clock signal (Clk_c). The positive clock edge for DDR refers to the point where the rising true clock signal Clk_t crosses the falling complementary clock signal Clk_c, while the negative clock edge indicates the transition of the falling true clock signal Clk_t and the rising of the complementary clock signal Clk_c. Commands (e.g., read command, write command, etc.) are typically entered on the positive edges of the clock signal and data is transmitted or received on both the positive and negative clock edges.

The clock input circuit 18 receives the true clock signal (Clk_t) and the complementary clock signal (Clk_c) and generates an internal clock signal CLK. The internal clock signal CLK is supplied to an internal clock generator 30, such as a delay locked loop (DLL) circuit. The internal clock generator 30 generates a phase controlled internal clock signal LCLK based on the received internal clock signal CLK. The phase controlled internal clock signal LCLK is supplied to the input/output (I/O) interface 16, for instance, and is used as a timing signal for determining an output timing of read data.

The internal clock signal CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For example, the command decoder 32 may provide command signals to the internal clock generator 30 over the bus 36 to coordinate generation of the phase controlled internal clock signal LCLK. The phase controlled internal clock signal LCLK may be used to clock data through the I/O interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes a bank control block 22 which provides decoding (e.g., row decoder and column decoder), as well as other features, such as timing control and data control, to facilitate the execution of commands to and from the memory banks 12. Collectively, the memory banks 12 and the bank control blocks 22 may be referred to as a memory array 23.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20 which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 16. More specifically, the data may be sent to or retrieved from the memory banks 12 over the data bus 46, which includes a plurality of bi-directional data buses. Data I/O signals, generally referred to as DQ signals, are generally transmitted and received in one or more bi-directional data busses. For certain memory devices, such as a DDR5 SDRAM memory device, the I/O signals may be divided into upper and lower bytes. For instance, for an x16 memory device, the I/O signals may be divided into upper and lower I/O signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the data strobe (DQS) signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

An impedance (ZQ) calibration signal may also be provided to the memory device 10 through the I/O interface 16. The ZQ calibration signal may be provided to a reference pin and used to tune output drivers and on die termination values (ODT) by adjusting pull-up and pull-down resistors of the memory device 10 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the I/O pins.

In addition, a loopback signal (LOOPBACK) may be provided to the memory device 10 through the I/O interface 16. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the I/O interface 16.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into a memory system incorporating the memory device 10. Accordingly, it should be understood that the block diagram of FIG. 1 is only provided to highlight certain functional features of the memory device 10 to aid in the subsequent detailed description.

In some embodiments, the memory device 10 may be disposed in (physically integrated into or otherwise connected to) a host device or otherwise coupled to a host device. The host device may include any one of a desktop computer, laptop computer, pager, cellular phone, personal organizer, portable audio player, control circuit, camera, etc. The host device may also be a network node, such as a router, a server, or a client (e.g., one of the previously-described types of computers). The host device may be some other sort of electronic device, such as a copier, a scanner, a printer, a game console, a television, a set-top video distribution or recording system, a cable box, a personal digital media player, a factory automation system, an automotive computer system, or a medical device. (The terms used to describe these various examples of systems, like many of the other terms used herein, may share some referents and, as such, should not be construed narrowly in virtue of the other items listed.)

The host device may, thus, be a processor-based device, which may include a processor, such as a microprocessor, that controls the processing of system functions and requests in the host. Further, any host processor may comprise a plurality of processors that share system control. The host processor may be coupled directly or indirectly to additional system elements of the host, such that the host processor controls the operation of the host by executing instructions that may be stored within the host or external to the host.

As discussed above, data may be written to and read from the memory device 10, for example, by the host whereby the memory device 10 operates as volatile memory, such as Double Data Rate DRAM (e.g., DDR5 SDRAM). The host may, in some embodiments, also include separate non-volatile memory, such as read-only memory (ROM), PC-RAM, silicon-oxide-nitride-oxide-silicon (SONOS) memory, metal-oxide-nitride-oxide-silicon (MONOS) memory, polysilicon floating gate based memory, and/or other types of flash memory of various architectures (e.g., NAND memory, NOR memory, etc.) as well as other types of memory devices (e.g., storage), such as solid state drives (SSD's), MultimediaMediaCards (MMC's), SecureDigital (SD) cards, CompactFlash (CF) cards, or any other suitable device. Further, it should be appreciated that the host may include one or more external interfaces, such as Universal Serial Bus (USB), Peripheral Component Interconnect (PCI), PCI Express (PCI-E), Small Computer System Interface (SCSI), IEEE 1394 (Firewire), or any other suitable interface as well as one or more input devices to allow a user to input data into the host, for example, buttons, switching elements, a keyboard, a light pen, a stylus, a mouse, and/or a voice recognition system, for instance. The host may optionally also include an output device, such as a display coupled to the processor and a network interface device, such as a Network Interface Card (NIC), for interfacing with a network, such as the Internet. As will be appreciated, the host may include many other components, depending on the application of the host.

The host may operate to transfer data to the memory device 10 for storage and may read data from the memory device 10 to perform various operations at the host. Accordingly, to facilitate these data transmissions, in some embodiments, the I/O interface 16 may include a data transceiver 48 that operates to receive and transmit DQ signals to and from the I/O interface 16.

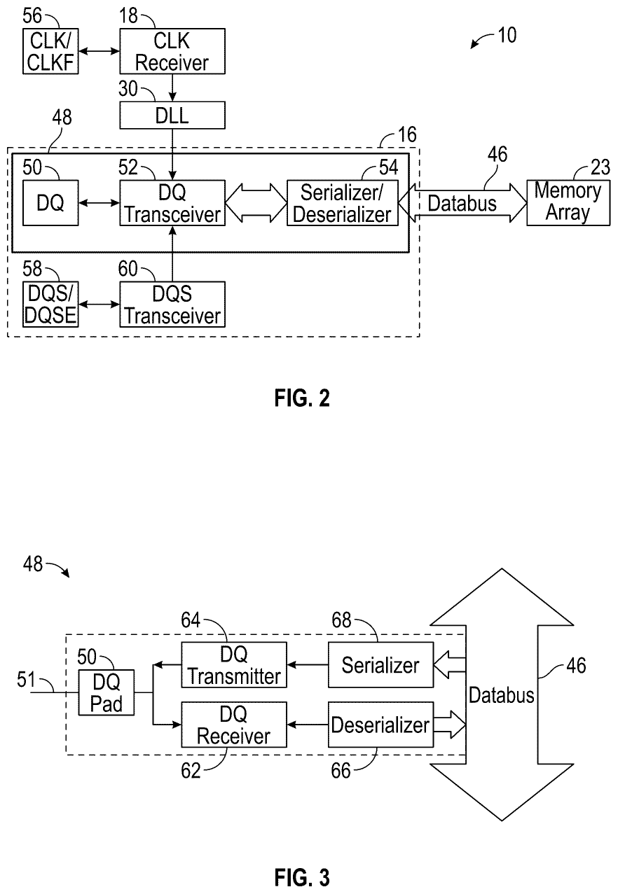

FIG. 2 illustrates the I/O interface 16 of the memory device 10 generally and, more specifically, the data transceiver 48. As illustrated, the data transceiver 48 of the I/O interface 16 may include a DQ connector 50, a DQ transceiver 52, and a serializer/deserializer 54. It should be noted that in some embodiments, multiple data transceivers 48 may be utilized whereby each single data transceiver 48 may be utilized in connection with a respective one of each of upper and lower I/O signals (e.g., DQ<15:8> and DQ<7:0>) corresponding to upper and lower bytes of the data signals, for instance. Thus, the I/O interface 16 may include a plurality of data transceivers 48, each corresponding to one or more I/O signals (e.g., inclusive of a respective DQ connector 50, DQ transceiver 52, and serializer/deserializer 54).

The DQ connector 50 may be, for example a pin, pad, combination thereof, or another type of interface that operates to receive DQ signals, for example, for transmission of data to the memory array 23 as part of a data write operation. Additionally, the DQ connector 50 may operate to transmit DQ signals from the memory device 10, for example, to transmit data from the memory array 23 as part of a data read operation. To facilitate these data reads/writes, a DQ transceiver 52 is present in data transceiver 48. In some embodiments, for example, the DQ transceiver 52 may receive a clock signal generated by the internal clock generator 30 as a timing signal for determining an output timing of a data read operation from the memory array 23. The clock signal transmitted by the internal clock generator 30 may be based upon one or more clocking signals received by the memory device 10 at clock connector 56 (e.g., a pin, pad, the combination thereof, etc.) and routed to the internal clock generator 30 via the clock input circuit 18. Thus, the DQ transceiver 52 may receive a clock signal generated by the internal clock generator 30 as a timing signal for determining an output timing of a data read operation from the memory array 23.

The DQ transceiver 52 of FIG. 2 may also, for example, receive one or more DQS signals to operate in a strobe data mode as part of a data write operation. The signals may be received at a DQS connector 58 (e.g., a pin, pad, the combination thereof, etc.) and routed to the DQ transceiver 52 via a DQS transceiver 60 that operates to control a data strobe mode via selective transmission of the DQS signals to the DQ transceiver 52. Thus, the DQ transceiver 52 may receive DQS signals to control a data write operation from the memory array 23.

As noted above, the data transceiver 48 may operate in modes to facilitate the transfers of the data to and from the memory device 10 (e.g., to and from the memory array 23). For example, to allow for higher data rates within the memory device 10, a data strobe mode in which DQS signals are utilized, may occur. The DQS signals may be driven by an external processor or controller sending the data (e.g., for a write command) as received by the DQS connector 58 (e.g., a pin, pad, the combination thereof, etc.). In some embodiments, the DQS signals are used as clock signals to capture the corresponding input data.

In addition, as illustrated in FIG. 2, the data transceiver 48 also includes a serializer/deserializer 54 that operates to translate serial data bits (e.g., a serial bit stream) into parallel data bits (e.g., a parallel bit stream) for transmission along data bus 46 during data write operations of the memory device 10. Likewise, the serializer/deserializer 54 operates to translate parallel data bits (e.g., a parallel bit stream) into serial data bits (e.g., a serial bit stream) during read operations of the memory device 10. In this manner, the serializer/deserializer 54 operates to translate data received from, for example, a host device having a serial format into a parallel format suitable for storage in the memory array 23. Likewise, the serializer/deserializer 54 operates to translate data received from, for example, the memory array 23 having a parallel format into a serial format suitable for transmission to a host device.

FIG. 3 illustrates the data transceiver 48 as including the DQ connector 50 coupled to data transfer bus 51, a DQ receiver 62, a DQ transmitter 64 (which in combination with the DQ receiver 62 forms the DQ transceiver 52), a deserializer 66, and a serializer 68 (which in combination with the deserializer 66 forms the serializer/deserializer 54). In operation, the host (e.g., a host processor or other memory device described above) may operate to transmit data in a serial form across data transfer bus 51 to the data transceiver 48 as part of a data write operation to the memory device 10. This data is received at the DQ connector 50 and transmitted to the DQ receiver 62. The DQ receiver 62, for example, may perform one or more operations on the data (e.g., amplification, driving of the data signals, etc.) and/or may operate as a latch for the data until reception of a respective DQS signal that operates to coordinate (e.g., control) the transmission of the data to the deserializer 66. As part of a data write operation, the deserializer 66 may operate to convert (e.g., translate) data from a format (e.g., a serial form) in which it is transmitted along data transfer bus 51 into a format (e.g., a parallel form) used for transmission of the data to the memory array 23 for storage therein.

Likewise, during a read operation (e.g., reading data from the memory array 23 and transmitting the read data to the host via the data transfer bus 51), the serializer 68 may receive data read from the memory array 23 in one format (e.g., a parallel form) used by the memory array 23 and may convert (e.g., translate) the received data into a second format (e.g., a serial form) so that the data may be compatible with one or more of the data transfer bus 51 and/or the host. The converted data may be transmitted from the serializer 68 to the DQ transmitter 64, whereby one or more operations on the data (e.g., de-amplification, driving of the data signals, etc.) may occur. Additionally, the DQ transmitter 64 may operate as a latch for the received data until reception of a respective clock signal, for example, from the internal clock generator 30, that operates to coordinate (e.g., control) the transmission of the data to the DQ connector 50 for transmission along the data transfer bus 51 to one or more components of the host.

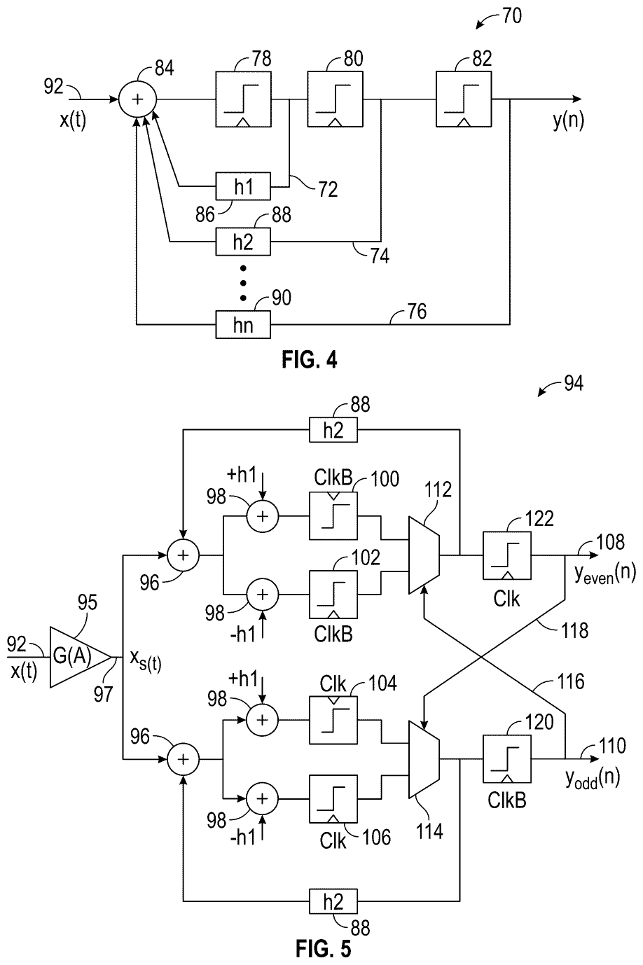

In some embodiments, the data received at the DQ connector 50 may be distorted. For example, data received at the DQ connector 50 may be affected by inter-symbol interference (ISI) in which previously received data interferes with subsequently received data. For example, due to increased data volume being transmitted across the data transfer bus 51 to the DQ connector 50, the data received at the DQ connector 50 may be distorted relative to the data transmitted by the host. One technique to mitigate (e.g., offset or cancel) this distortion and to effectively reverse the effects of ISI is to apply an equalization operation to the data. FIG. 4 illustrates an embodiment of an equalizer that may be used in this equalization operation.

FIG. 4 illustrates one embodiment an equalizer, in particular, a decision feedback equalizer (DFE) 70. As illustrated, the DFE 70 represents an N-tap DFE 70, where “N” is a positive integer value. For example, a 1-tap DFE, a 2-tap DFE, a 3-tap DFE, a 4 tap DFE or another N-tap DFE may be implemented as the DFE 70. The DFE 70 may be disposed separate from or internal to the deserializer 66 or the DQ receiver 62 of FIG. 3. In operation, a binary output (e.g., from a latch or decision-making slicer) is captured in one or more data latches or data registers. In the present embodiment, these data latches or data registers may be disposed in the deserializer 66 and the values stored therein may be latched or transmitted along paths 72, 74, and 76.

When a data bit is received at the DQ receiver 62, it may be identified as being transmitted from the host as bit “x(t)” and may be received at a time to as distorted bit x (e.g., bit x having been distorted by ISI). The most recent bit received prior to distorted bit x being received at the DQ receiver 62, e.g., received at time of t₋₁ that immediately precedes time of t₀, may be identified as x−1 and is illustrated as being transmitted from a data latch 78 along path 72. The second most recent bit received prior to distorted bit x being received at the DQ receiver 62, e.g., received at time of t₋₂ that immediately precedes time of t₋₁, may be identified as x−2 and is illustrated as being transmitted from data latch 80 along path 74. This process can continue with additional latches until latch 82, which corresponds to the Nth latch and transmits the least recent bit (x−N) received prior to distorted bit x being received at the DQ receiver 62, e.g., received at time of t_{-N} that immediately precedes time of t_{-N-1}, which is transmitted along path 76. Bits x−1, x−2, . . . x−N may be considered the group of bits that interfere with received distorted bit x (e.g., bits x−1, x−2, . . . x−N cause ISI to host transmitted bit x) and the DFE 70 may operate to offset the distortion caused by the group of bits x−1, x−2, . . . x−N on host transmitted bit x.

Thus, the values latched or transmitted along paths 72, 74, and 76, may correspond, respectively, to the most recent previous data values (e.g., preceding bits x−1, x−2, . . . x−N) transmitted from the DQ receiver 62 to be stored in memory array 23. These previously transmitted bits are fed back along paths 72, 74, and 76 and are used in generation of weighted tap 86 (e.g., h1), weighted tap 88 (e.g., h2), and weighted tap 90 (e.g., hn) represented as being disposed along paths 72, 74, and 76. Weighted tap 86, weighted tap 88, and weighted tap 90 can each correspond to respective adjustments (e.g., voltages) that may be and added to the received input signal (e.g., data received from the DQ connector 50, such as distorted bit x) by means of the summer 84 (e.g., a summing amplifier). In other embodiments, weighted tap 86, weighted tap 88, and weighted tap 90 may be combined with an initial reference value to generate an offset that corresponds to or mitigates the distortion of the received data (e.g., mitigates the distortion of distorted bit x). In some embodiments, taps are weighted to reflect that the most recent previously received data (e.g., bit x−1 and weighted tap 86) may have a stronger influence on the distortion of the received data (e.g., distorted bit x) than bits received at earlier times (e.g., bits x−2 and x−N). The DFE 70 may operate to generate magnitudes and polarities for weighted tap 86, weighted tap 88, and weighted tap 90 due to each previous bit to collectively offset the distortion caused by those previously received bits.

For example, for the present embodiment, each of previously received bits x−1, x−2, x−3, and x−4 (as bit x−N) could have had one of two values (e.g., a binary 0 or 1), which was transmitted to the deserializer 66 for transmission to the memory array 23 and, additionally, latched or saved in a register for subsequent transmission along respective paths 72, 74, 76, and an additional path corresponding to previously received bit x−3. In this example, sixteen (e.g., 2⁴) possible binary combinations (e.g., 0000, 0001, 0010, . . . , 1110, or 1111) for the group of bits x−1, x−2, x−3, and x−4 would be possible. The DFE 70 operates to select and/or generate corresponding tap values for whichever of the aforementioned sixteen combinations are determined to be present (e.g., based on the received values along paths 72, 74, 76, and the additional path corresponding to previously received bit x−3) to be used to adjust either the input value received from the DQ connector 50 (e.g., distorted bit x) or to modify a reference value that is subsequently applied to the input value received from the DQ connector 50 (e.g., distorted bit x) so as to cancel the ISI distortion from the previous bits in the data stream (e.g., the group of bits x−1, x−2, x−3, and x−4).

Use of distortion correction (e.g., a DFE 70) may be beneficial such that data transmitted from the DQ connector 50 is correctly represented in the memory array 23 without distortion. As noted above, distortion correction circuitry (e.g., equalizer) may be included as part of the DQ receiver 62 but may not be required to be physically located there (e.g., it may instead be coupled to the DQ receiver 62). In some embodiments, the distortion correction circuitry may be operated to provide previously transmitted bit data to correct a distorted bit 81 (e.g., bit having been distorted by ISI and/or system distortions) transmitted via a channel 92 (e.g., connection, transmission line, and/or conductive material).

FIG. 5 illustrates a DFE 94 as an embodiment of an equalizer discussed above. DFE 94 represents a half rate DFE receiver where data (from channel 92) is received at both edges of a clock signal at a frequency of half of the data rate transmitted along channel 92. As illustrated, the DFE 94 represents a 2-tap DFE. However, other variations are contemplated, for example, a 1-tap DFE, a 3-tap DFE, a 4-tap DFE or another N-tap DFE may be implemented as the DFE 94. The DFE 94 may be disposed separate from or internal to the deserializer 66 or the DQ receiver 62 of FIG. 3.

Distorted bit(s) may be transmitted to an amplifying device 95 from a channel 92. The amplifying device 95 may be, for example, a variable gain amplifier coupled to the DFE 94. In some embodiments, the amplifying device 95 may be a two stage amplifier with Continuous Time Linear Equalization (CTLE) in one of the stages of the amplifier. The distorted bit may be transmitted simultaneously with a DQ reference signal having a predetermined voltage (VRDQ) to the DFE 124. VRDQ may represent a threshold value (e.g., a voltage level) for determination if the transmitted bit received by the DQ connector 50 was a logical low (e.g., 0) or a logical high (e.g., 1). Thus, data bits may be received at a first input of the amplifying device 95 and a reference signal (e.g., VRDQ) may be received at a second input of the amplifying device 95.

In some embodiments, as noted above, the amplifying device 95 of FIG. 5 may represent a variable gain amplifier and continuous-time linear equalizer (CTLE). The output of the variable gain amplifier (e.g., Xs(t)) may be set to predetermined levels (e.g., settings), for example, values approximately between 0.5 times and 2.0 times the DC reference signal input to the variable gain amplifier or another level. The CTLE may operate to, for example, mitigate inter-symbol interference (ISI). More particularly, the CTLE generally operates to offset losses in the data stream (leading to a distorted bit) caused by, for example, the channel 92. The CTLE can generally operate to amplify higher frequency content of the data stream to equalize for these effects to the data stream (i.e., to boost higher frequency content, therefore making it effectively equivalent to amplitude at lower frequency components of the data stream). Accordingly, use of a CTLE in addition to a variable gain amplifier can operate to provide more reliable signals to the DFE 94 (e.g., increase the reliability of one or more of the distorted bit).

In some embodiments, the CTLE can be integrated into the amplifying device 95 (e.g., a portion of one of the stages of a variable gain amplifier). However, it should be noted that the CTLE circuitry can instead, for example, be disposed separately from (i.e., in series with) a variable gain amplifier used in the amplifying device 95. As illustrated, the amplifying device 95 receives data bits along channel 92, as well a reference signal, VRDQ (e.g., the DQ reference signal or “Vref”) and transmits an amplified result along path 97 to summers 96.

The DFE 94 includes a first stage of summers 96 that each receive a second weighted tap (e.g., h2) as a feedback signal. Additionally, the first stage of summers 96 receive the data stream along channel 92 (e.g., bits x, x−1, x−2, etc.). Additionally, the DFE 94 is a speculative equalizer. Accordingly, a first weighted tap (e.g., h1) is transmitted as an input to a second stage of summers 98. As illustrated, the first weighted tap is implemented via speculation, so a positive weighted tap value (e.g., +h1) and a negative weighted tap value (e.g., −h1) are provided to the second stage of summers 98.

The DFE 94 further includes latch 100, latch 102, latch 104, and latch 106 (e.g., data slicers). These latches 100, 102, 104, and 106 are controlled by a clock signal CLK. CLK may be a half-rate clock signal, whereby latches 100 and 102 sample data on a rising edge of CLK to generate even data bits, which are output from the DFE 94 along path 108. Likewise, latches 104 and 106 sample data on a falling edge of CLK to generate odd data bits, which are output from the DFE 94 along path 110. The sampled data from latch 100 and latch 102 is transmitted to a selection circuit 112 while the sampled data from latch 104 and latch 106 is transmitted to a selection circuit 114. Selection circuit 112 and selection circuit 114 can be 2-to-1 multiplexers.

Selection circuit 112, as illustrated, is controlled by a feedback signal transmitted along path 116 and selection circuit 114 is controlled by a feedback signal transmitted along path 118. In operation, the feedback signal along path 116 operates to select the correct weighed tap value (e.g., +h1 or −h1) to be applied by selecting the respective input to the selection circuit 112 that corresponds to that correct weighted tap value as the signal output from the selection circuit 112. Similarly, the feedback signal along path 118 operates to select the correct weighed tap value (e.g., +h1 or −h1) to be applied by selecting the respective input to the selection circuit 112 that corresponds to that correct weighted tap value as the signal output from the selection circuit 114. Furthermore, as illustrated, the feedback signal along path 116 provides the selection signal to an even bit portion of the DFE 94 (i.e., the upper illustrated portion of the DFE 94), since any previous bit was decided by the odd portion of the DFE 94, inclusive of latch 120) and the feedback signal along path 118 provides the selection signal to an odd bit portion of the DFE 94 (i.e., the lower illustrated portion of the DFE 94), since any previous bit was decided by the even portion of the DFE 94 inclusive of latch 122.

In operation, the tap signal path of Tap1 (i.e., providing h1 to the second stage of summers 98) is t_{clk-to-Q}+tu, where t_{clk-to-Q} is the clock-to-Q delay of the respective latches 100, 102, 104, or 106 for a given (e.g., selected) path and tu is the propagation delay of the respective selection circuit 112, 114 for the given (e.g., selected) path. However, the tap signal path of Tap2 (i.e., providing h2 to the first stage of summers 96) is greater than the tap signal path of Tap1. The tap signal path of Tap2 is t_{clk-to-Q}+tu+ts, where t_{clk-to-Q} is the clock-to-Q delay of the respective latches 100, 102, 104, or 106 for a given (e.g., selected) path, tu is the propagation delay of the respective selection circuit 112, 114 for the given (e.g., selected) path, and ts is the settling time attributable to the first stage of summers 96.

As operating speeds increase, the propagation delays described above, particularly with respect to, for example, tap signal path of Tap1 and Tap2, can affect the operation of the DFE 94. This can be due to the propagation delay (e.g., tu) of the respective selection circuit 112, 114 for the given (e.g., selected) path. Indeed, as operating speeds increase, the tap signal path of Tap 1 (i.e., providing h1 to the second stage of summers 98) or Tap2 (i.e., providing h2 to the first stage of summers 96), for example, can arrive subsequent to the data being provided from channel 92 due primarily to the propagation delay (e.g., tu) of the respective selection circuit 112, 114 for the given (e.g., selected) path. Therefore, the weighting value associated with one or both of h1 and h2 will not be correctly applied to the data (i.e., bit) being transmitted to the first stage of summers 96 and/or the second stage of summers 98.

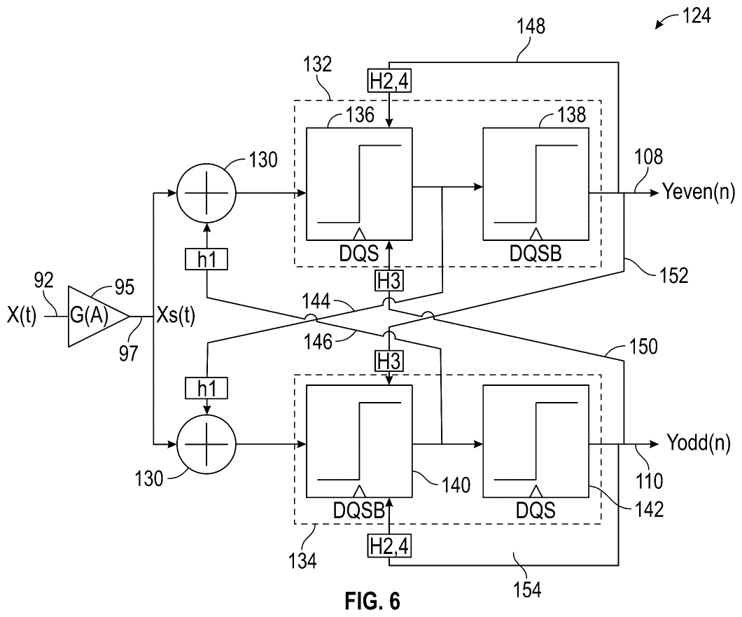

FIG. 6 illustrates DFE 124 as an embodiment of an equalizer discussed above that can overcome the delay issues associated with the propagation delay (e.g., tu) of the respective selection circuit 112, 114 for the given (e.g., selected) path in DFE 94. DFE 124 represents a half rate unroll (no mux) DFE receiver where data (from channel 92) is received at both edges of a clock signal at a frequency of half of the data rate transmitted along channel 92. However, there is no unroll MUX delay (i.e., tu propagation delay) such as that associated with DFE 94 of FIG. 5. As illustrated, the DFE 124 represents a 4-tap DFE. However, other variations are contemplated, for example, a 1-tap DFE, a 2-tap DFE, a 3-tap DFE or another N-tap DFE may be implemented as the DFE 124. The DFE 124 may be disposed separate from or internal to the deserializer 66 or the DQ receiver 62 of FIG. 3.

Distorted bit(s) may be transmitted to the amplifying device 95 from a channel 92 and transmitted from the amplifying device 95 to the DFE 124. The amplifying device 95, as previously described, may be, for example, a variable gain amplifier, such as a two stage amplifier with Continuous Time Linear Equalization (CTLE) in one of the stages of the amplifier. In some embodiments, the CTLE can be integrated into the amplifying device 95 (e.g., a portion of one of the stages of a variable gain amplifier). However, it should be noted that the CTLE circuitry can instead, for example, be disposed separately from (i.e., in series with) a variable gain amplifier used in the amplifying device 95. As illustrated, the amplifying device 95 receives data bits along channel 92, as well a reference signal, VRDQ (e.g., the DQ reference signal or “Vref”) and transmits an amplified result along path 97 to summers 130.

In the illustrated example, the DFE 124 may be operated to correct the distortion from the distorted bit (e.g., bit x) using the tap weighted with previous bit data. Data (e.g., logical 1 or logical 0) for a given bit may be passed through the amplifying device 95 and may be transmitted through the path 128 to summers 130. The magnitudes and polarities of a weighted tap 86 (e.g., h1) may offset the total distortion caused by the x−1 bit via summers 130, which can operate as current summers that apply current to the distorted bit x to offset for distortion caused by the x−1 bit. The resultant signals output from the summers 130 are transmitted to a double tail latch 132 in an even bit portion of the DFE 124 (i.e., the upper illustrated portion of the DFE 124) and a double tail latch 134 in an odd bit portion of the DFE 124 (i.e., the lower illustrated portion of the DFE 94). The double tail latch 132 can include latch 136 and latch 138 while the double tail latch 134 can include latch 140 and latch 142. In operation latch 136 and latch 138 may operate in a manner similar to, for example, latch 100 and 122 and latch 140 and latch 142 may operate in a manner similar to, for example, latch 104 and 120. However, as illustrated, there is no selection circuit 112 or selection circuit 114 and, accordingly, no corresponding tu as propagation delay in the DFE 124. This can save approximately, for example, 60 psec, 70 70 psec, 80 psec, 90 psec, 100 psec or another amount of time with respect to the looptime margin of DFE 124 with respect to the looptime margin of DFE 94.

Path 144 operates as a feedback path transmitting a first weighted tap (h1) from an output of latch 136 to the summer 130 disposed in the odd bit portion of the DFE 124. Similarly, path 146 operates as a feedback path transmitting the first weighted tap (h1) from an output of latch 140 to the summer 130 disposed in the even bit portion of the DFE 124. Additionally, as illustrated, the timing of the output of latch 136 is controlled by the DQS signal while the timing of the output of latch 138 is controlled by the inverse of the DQS signal, DQSB. The timing of the output of latch 140 is controlled by DQSB and the timing of the output of latch 142 is controlled by DQS. The signal generated by latch 136 is based upon the output from the summer 130 disposed in the even bit portion of the DFE 124, as adjusted by a second weighted tap (h2) received from the output of latch 138 along path 148, a fourth weighted tap (h4) received from the output of latch 138 along path 148, and a third weighted tap (h3) received from the output of latch 142 along path 150. As noted above, the output of latch 136 is the resultant signal modified by the aforementioned weighted taps (h2, h3, and h4) and is transmitted along path 144, where it is used in the generation of the first weighted tap (h1) transmitted to the summer 130 disposed in the odd bit portion of the DFE 124. Additionally, the output of latch 136 is transmitted to latch 138 as an input signal to latch 138.

Latch 138 generates an output as controlled by the DSQB signal and this output is transmitted as the second weighted tap (h2) or the fourth weighted tap (h4) along path 148 to latch 136 or is transmitted as a third weighted tap (h3) to latch 140, depending on the state of operation of the double tail latch 132. For example, whether the output is transmitted as the second weighted tap (h2), the fourth weighted tap (h4) along path 148 to latch 136, or is transmitted as a third weighted tap (h3) to latch 140 depends on the phase of the DQSB signal (e.g., 0°, 90°, 180°, or) 270° that is being applied as a control signal for the latch 138. The output of latch 138 is also transmitted as the even data bits, which are output from the DFE 124 along path 108.

As additionally illustrated, the signal generated by latch 140 is based upon the output from the summer 130 disposed in the odd bit portion of the DFE 124, as adjusted by a second weighted tap (h2) received from the output of latch 142 along path 154, a fourth weighted tap (h4) received from the output of latch 142 along path 154, and a third weighted tap (h3) received from the output of latch 138 along path 152. As noted above, the output of latch 140 is the resultant signal modified by the aforementioned weighted taps (h2, h3, and h4) and is transmitted along path 146, where it is used in the generation of the first weighted tap (h1) transmitted to the summer 130 disposed in the even bit portion of the DFE 124. Additionally, the output of latch 140 is transmitted to latch 142 as an input signal to latch 138.

Latch 142 generates an output as controlled by the DSQB signal and this output is transmitted as the second weighted tap (h2) or the fourth weighted tap (h4) along path 154 to latch 140 or is transmitted as a third weighted tap (h3) along path 150 to latch 136, depending on the state of operation of the double tail latch 134. For example, whether the output is transmitted as the second weighted tap (h2), the fourth weighted tap (h4) along path 154 to latch 140, or is transmitted as a third weighted tap (h3) to latch 136 depends on the phase of the DQS signal (e.g., 0°, 90°, 180°, or) 270° that is being applied as a control signal for the latch 138. The output of latch 142 is also transmitted as the odd data bits, which are output from the DFE 124 along path 110.

Regarding the first weighted tap (h1) provided to each of the summers 130, it should be noted that the signal transmitted to the summers 130 may be selectively positive (i.e., +h1) or negative (i.e., −h1) as selectable by summers. That is, a first weighted tap can be provided as both a positive weighted tap value (e.g., +h1) and a negative weighted tap value (e.g., −h1). Additionally, in operation, the tap signal path of Tap1 (i.e., providing h1 to the summers 130) is t_{clk-to-Q}+ts, where t_{clk-to-Q} is the clock-to-Q delay of the respective latches 138, 138, 140, or 142 for a given (e.g., selected) path and ts is the settling time attributable to the summers 130. The tap signal path of Tap2 is t_{clk-to-Q}. In this manner, tu (i.e., the propagation delay of any selection circuit) is omitted from the DFE 124 and ts is the settling time attributable to the first stage of summers 96.

Because tu is omitted in the DFE 124, as operating speeds increase, the propagation delays described above with respect to DFE 94 can be avoided. For example, as operating speeds increase, the tap signal path of Tap2 (i.e., providing h2 to the first stage of the double tail latch 132 and the first stage of the double tail latch 134), for example, can arrive before data being provided from channel 92. Therefore, the weighting value associated with h2 will be correctly applied to the data (i.e., bit) being transmitted to the respective latch 136 and latch 140.

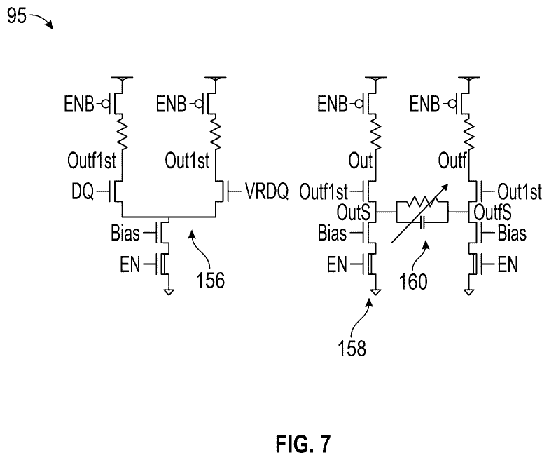

FIG. 7 illustrates an example of a first embodiment of an amplifying device 95 usable in conjunction with a DFE, for example, DFE 94 and/or DFE 124. The amplifying device 95 is a variable gain amplifier (VGA) and is illustrated as a two stage amplifier with a first VGA stage 156 and a second VGA stage 158 having Continuous Time Linear Equalization (CTLE) circuitry 160 therein. As illustrated, the first VGA stage 156 receives both DQ and reference signal VRDQ as gate signals and generates output signals Out1st and Outf1st (the inverted signal of Out1st) as gate signals for the second VGA stage 158. These gate signals (Out1st and Outf1st) are utilized in generation of output signals OutS and OutfS (where OutfS is the inverted output of OutS). OutS and OutfS can be read as signals related to the Out and Outf, which themselves can that constitute the Xs (t) output from the amplifying device 95 coupled to the DFE 94 of FIG. 5 or the DFE 124 of FIG. 6. That is, OutS and OutfS can constitute the Xs (t) output from the amplifying device 95 to the DFE 94 of FIG. 5 and the DFE 124 of FIG. 6.

As noted above, the amplifying device 95 includes a first VGA stage 156 and a second VGA stage 158. Use of two stages in the amplifying device can increase the boost (e.g., signal amplification) and inclusion of the CTLE circuitry allows for fully differential signaling to be implemented. However, there may be potential issues when the amplifying device 95 is utilized. For example, when a DDR rank margining tool (RMT) is utilized to provide automated memory margin testing to identify DDR margins at the rank level, it provides automated margining of DDR Vref and timing parameters at the DIMMs with applied stress patterns. However, changing the Vref ranges (e.g., changing VRDQ) can cause DC margin variations making it difficult to set desired (e.g., optimum) DC-operating points (e.g., the DC common mode voltage) in the amplifying device 95.

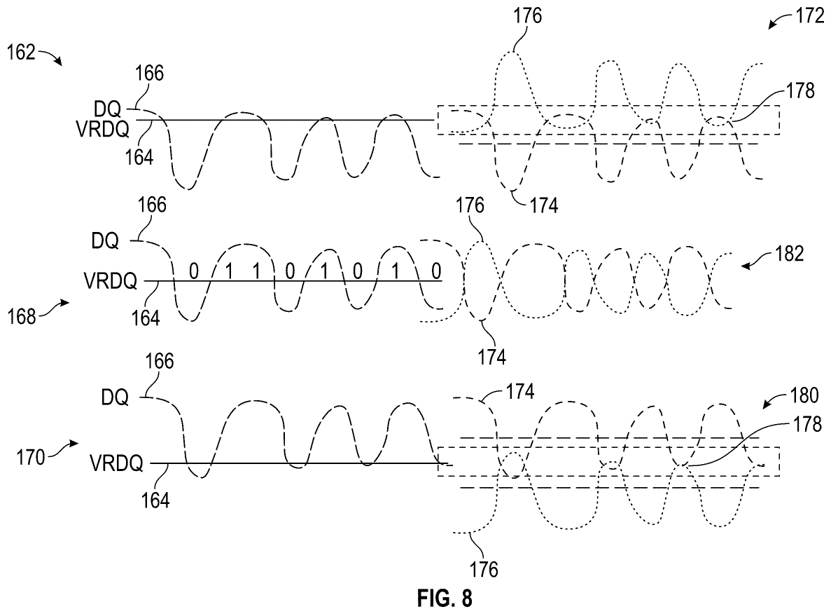

FIG. 8 illustrates examples of voltage graphs when different references voltages (e.g., changing VRDQ) are provided to the amplifying device 95 of FIG. 7. As illustrated in graph 162, the voltage level of VRDQ 164 is provided as having a value near the voltage high level of DQ 166. In graph 168, the voltage level of VRDQ 164 is provided as having a value near a mid-point voltage high level of DQ 166. In graph 170, the voltage level of VRDQ 164 is provided as having a value near a voltage low level of DQ 166. In this manner, graph 162, graph 168, and graph 170 illustrate examples of varying VRDQ 164.

Graph 172 illustrates Out1st 174 and Outf1st 176 as the outputs generated by the first VGA stage 156 in conjunction with the voltage level of VRDQ 164 and DQ 166 illustrated in graph 162. As illustrated in graphs 162 and 172, when DQ 166 is at its low voltage (i.e., “0”), Out1st 174 is also low (e.g., “0”) and Outf1st 176 is the inverse of Out1st 174 (i.e., high or “1”). However, when DQ 166 is at its high voltage (i.e., “1”), this value is close in value to the voltage level of VRDQ 164. This leads to the resultant output voltages Out1st 174 and Outf1st 176 being close in their voltage values, as illustrated in region 178 of graph 172. This can lead to issues in transmission of the Out1st 174 and Outf1st 176 as having correct values inverse from one another. Similarly, graph 180 illustrates Out1st 174 and Outf1st 176 as the outputs generated by the first VGA stage 156 in conjunction with the voltage level of VRDQ 164 and DQ 166 illustrated in graph 170. As illustrated in graphs 170 and 180, when DQ 166 is at its high voltage (i.e., “1”), Out1st 174 is also high (e.g., “1”) and Outf1st 176 is the inverse of Out1st 174 (i.e., low or “0”). However, when DQ 166 is at its low voltage (i.e., “0”), this value is close in value to the voltage level of VRDQ 164. This leads to the resultant output voltages Out1st 174 and Outf1st 176 being close in their voltage values, as illustrated in region 178 of graph 180. This can lead to issues in transmission of the Out1st 174 and Outf1st 176 as having correct values inverse from one another.

In contrast, graph 182 illustrates Out1st 174 and Outf1st 176 as the outputs generated by the first VGA stage 156 in conjunction with the voltage level of VRDQ 164 and DQ 166 illustrated in graph 168. As illustrated in graphs 168 and 182, when DQ 166 is at its high voltage (i.e., “1”), Out1st 174 is also high (e.g., “1”) and Outf1st 176 is the inverse of Out1st 174 (i.e., low or “0”). Likewise, when DQ 166 is at its low voltage (i.e., “0”), Out1st 174 is also low (e.g., “0”) and Outf1st 176 is the inverse of Out1st 174 (i.e., high or “1”). Because the voltage level of VRDQ 164 is set at or approximately at the midpoint of DQ 166, it operates as a desirable DC-operating point (e.g., DC common mode) in the first VGA stage 156, since the resulting Out1st and Outf1st generated by the first VGA stage 156 are easily identifiable as inverses of one another, as illustrated in graph 182.

As noted above, and as illustrated in conjunction with FIG. 8, changing the Vref ranges (e.g., changing VRDQ 164) can cause DC margin variations making it difficult to set desired (e.g., optimum) DC-operating points (e.g., the DC common mode voltage) in the amplifying device 95. However, during operation, the DQ pins and the DQS pins are typically in same condition and utilize common control signals for their setting. Therefore, in some embodiments, DQ compensation can be achieved by DC-extraction from a DQS pin instead of from the DQ pin. While the DC-common mode value of DQ 166 is affected by RTM operation, (as noted above in conjunction with FIG. 8), the DC-common mode value of DQS is not affected or changes by RTM operation. Thus, as discussed below, the systems and techniques for DC-extraction from a DQS pin instead of from the DQ pin can be implemented to overcome the above noted challenges.

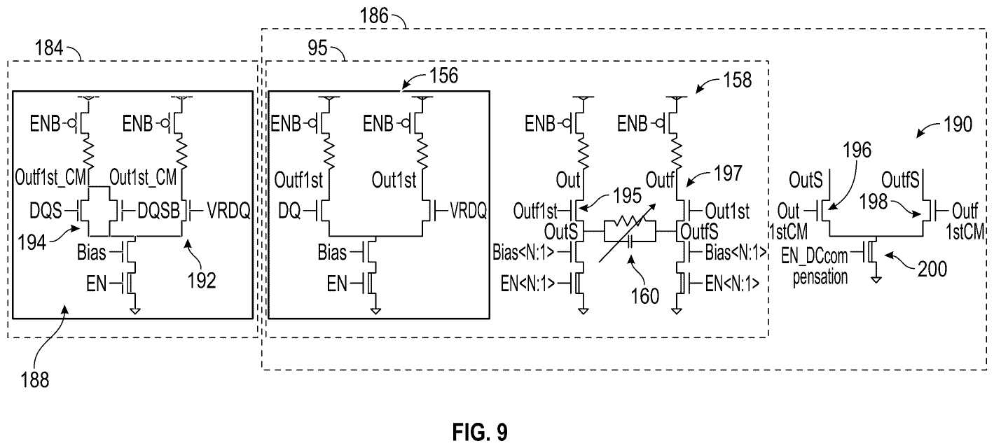

FIG. 9 illustrates a first embodiment of calibration circuitry utilized in conjunction with the amplifying device 95. More particularly, FIG. 7 illustrates pin area 184 and pin area 186. Pin area 184 may be, for example, a DQS pin area that includes a DQS pin (e.g., DQS connector 58) to receive a DQS signal as well as DC feedback stage 188. Pin area 184 may instead represent, for example, a DQSB pin area that includes a DQSB pin (e.g., DQSE connector 58) to receive a DQSB signal (i.e., the inverse of the DQS signal) as can additionally include DC feedback stage 188. It should be noted that I/O interface 16 may include one pin area 184 corresponding to a DQS pin area and one pin area 184 corresponding to a DQSB pin area. Pin area 186 may be, for example, a DQ pin area that includes a DQ pin (e.g., DQ connector 50) to receive a DQ signal as well as amplifying device 95 and DC compensation stage 190. In some embodiments, the I/O interface 16 may include eight of pin area 186.

As illustrated, the DC feedback stage 188 can generally mirror the first VGA stage 156. The first VGA stage 156 receives both DQ and VRDQ as gate signals and generates output signals Out1st and Outf1st (the inverted signal of Out1st) as gate signals for the second VGA stage 158. These gate signals (Out1st and Outf1st) are utilized in generation of output signals OutS and OutfS (where OutfS is the inverted output of OutS). OutS and OutfS can be read as signals related to the Out and Outf, which themselves can that constitute the Xs(t) output from the amplifying device 95 to the DFE 94 or the DFE 124 of FIG. 6. That is, OutS and OutfS can constitute the Xs(t) output from the amplifying device 95 to the DFE 94 of FIG. 5 or the DFE 124 of FIG. 6.

The DC feedback stage 188 can utilize the same resistors, enable signals (i.e., EN and ENB), and bias signal as the first VGA stage 156. Likewise, the right path 192 of the DC feedback stage 188 can be identical to the circuitry employed in the first VGA stage 156. However, in place of a single transistor receiving a DQ signal (as illustrated in the first VGA stage 156), the DC feedback stage 188 employs two transistors coupled in parallel in the left path 194 of the DC feedback stage 188. The gate of the first transistor of the pair of transistors in the left path 194 receives a DQS signal while the gate of the second transistor of the pair of transistors in the left path 194 receives a DQSB signal (i.e., the inverse of the DQS signal).

In operation, due to overlap of the right path 192 of the DC feedback stage 188 with the first VGA stage 156 and the similarities of the left path 194 of the DC feedback stage 188 with the first VGA stage 156, tracking of the DC-common mode value of the output of the first VGA stage 156 can be accomplished. For example, the DQS signal and the DQSB signal can be used in the generation of common mode output signals from the DC feedback stage 188; namely Out1st_CM (which corresponds to the similarly generated Out1st from the first VGA stage 156) and Outf1st_CM (the inverted signal of Out1st_CM), which corresponds to the similarly generated Outf1st from the first VGA stage 156. That is, while the first VGA stage 156 is generating its output signals Out1st and Outf1st in view of a changing VRDQ signal applied thereto, the DC feedback stage 188 is similarly generating its output signals Out1st_CM and Outf1st_CM in line with the same changing VRDQ signal applied thereto.

In this manner, the DC feedback stage 188 tracks the DC-common mode of the output of the first VGA stage 156 (i.e., Out1st and Outf1st). However, unlike the first VGA stage 156 which has its DC-common mode value of DQ affected, thus affecting its output signals Out1st and Outf1st, the DC feedback stage 188, having utilized DQS and DQSB which have DC-common mode values unchanged by varying VRDQ values, generates corresponding output signals Out1st_CM and Outf1st_CM with unaffected DC-common mode values.

The second VGA stage 158 receives the output signals (Out1st and Outf1st) from the first VGA stage 156 and applies them as gate signals in the generation of output signals OutS and OutfS (where OutfS is the inverted output of OutS). OutS and OutfS can be read as signals related to the Out and Outf, which themselves can that constitute the Xs(t) output from the amplifying device 95 coupled to the DFE 94 of FIG. 5 or the DFE 124 of FIG. 6. To correct for any DC bias of the output of the second VGA stage 158 (i.e., the output of the amplifying device 95), a DC compensation stage 190 is utilized.

DC compensation stage 190 includes a transistor 196 that receives OutS at its drain, as transmitted along a path coupled to a source of a transistor 195 in the second VGA stage 158. Transistor 196 also receives Out1st_CM at its gate, as transmitted along a path coupled to a node disposed above the parallel transistors in the left path 194 of the DC feedback stage 188. DC compensation stage 190 also includes a transistor 198 that receives OutfS at its drain, as transmitted along a path coupled to a source of a transistor 197 in the second VGA stage 158. Transistor 198 also receives Outf1st_CM at its gate, as transmitted from a path coupled to a node disposed above the transistors in the right path 192 of the DC feedback stage 188. Finally, the DC compensation stage 190 includes transistor 200. Transistor 200 receives a select signal (e.g., enable signal, EN_DCcompensation) at its gate that that operates to select/output (e.g., apply) the Out1st_CM and Outf1st_CM to compensate for the DC-bias in the output of the amplifying device 95. In this manner, calibration of the amplifying device 95 used in conjunction with the DFE 94 and the DFE 124 (or other DFE circuits) with respect to its DC-common mode when it receives varying Vref signals can be accomplished.

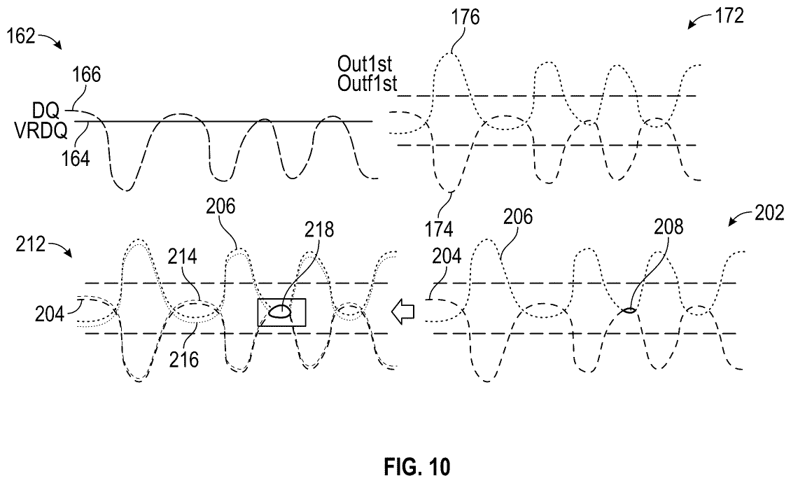

FIG. 10 illustrates examples of voltage graphs both utilizing and not utilizing the calibration circuitry and techniques described above with respect to FIG. 9. FIG. 10 illustrates n graph 162 (previously illustrated in FIG. 8) representing the reference voltage level (e.g., VRDQ 164) as being provided as having a value near the voltage high level of DQ 166. FIG. 10 also illustrates graph 172 (previously illustrated in FIG. 8) as representing Out1st 174 and Outf1st 176 as the outputs generated by the first VGA stage 156 in conjunction with the voltage level of VRDQ 164 and DQ 166 illustrated in graph 162 when no calibration of the amplifying device 95 has occurred.

Graph 202 is additionally illustrated in FIG. 10. Graph 202 represents the output signals Out 204 and Outf 206, where Outf 206 is the inverted output of Out 204. Out 204 and Outf 206 can constitute the Xs(t) output from the amplifying device 95 coupled to the DFE 94 of FIG. 5 or the DFE 124 of FIG. 6 and are presented in graph 202 when the circuitry and techniques of FIG. 9 are not applied. This leads to, for example, an eye 208 in graph 202 that is narrow, indicative of noise in the output signals Out 204 and Outf 206 and reduced reliability of those results. Graph 212 illustrates the output signals Out 214 and Outf 216 generated by the amplifying device 95 when a calibration of the amplifying device 95 has been applied to compensate for DC-bias of the amplifying device 95, as discussed above with respect to FIG. 9. As illustrated, the output signals Out 214 and Outf 216 generate an eye 218 in graph 212 that is larger than eye 208 of graph 202, indicative of reduced noise in the output signals Out 214 and Outf 216 and increased reliability of those results relative to signals Out 204 and Outf 206.

As illustrated at least in the results presented in graph 212 of FIG. 10, utilization of the systems and techniques for DC-extraction from a DQS pin instead of from the DQ pin, as described herein, can lead to improvements in voltage margin of the amplifying device 95. Moreover, these systems and techniques provide for calibration of the amplifying device 95 so as to, for example, reduce sensitivities of voltage noise and, correspondingly, to increase the reliability of the signals transmitted from the amplifying device 95.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. A device, comprising:
an amplifying device that when in operation transmits a data signal and a reference signal to a decision feedback equalizer (DFE) circuit, wherein the amplifying device comprises:
a variable gain amplifier (VGA) that when in operation generates the reference signal as having a predetermined gain relative to a received input signal; and
a continuous-time linear equalizer (CTLE) that operates to mitigate inter-symbol interference (ISI) on the data signal from a data stream comprising the data signal; and
compensation circuitry coupled to the amplifying device, wherein the compensation circuitry when in operation calibrates the amplifying device by adjusting a voltage level of the data signal based upon a data strobe (DQS) signal.

2. The device of claim 1, wherein the CTLE is internal to the VGA.

3. The device of claim 1, wherein the compensation circuitry comprises a first transistor comprising a first drain coupled to a stage of the VGA to receive a first signal output from the VGA and a first gate coupled to a feedback circuit of the device via a first path to receive a first compensation signal from the feedback circuit.

4. The device of claim 3, wherein the compensation circuitry comprises a second transistor comprising a second drain coupled to the stage of the VGA to receive a second signal output from the VGA and a second gate coupled to the feedback circuit of the device via a second path to receive a second compensation signal from the feedback circuit.

5. The device of claim 4, wherein the compensation circuitry comprises a third transistor coupled to the first transistor and the second transistor, wherein the third transistor comprises a third gate configured to receive an enable signal to control operation of the compensation circuitry.

6. The device of claim 4, comprising a data I/O signal (DQ) pad configured to receive the data stream, wherein the DQ pad comprises the amplifying device and the compensation circuitry.

7. The device of claim 6, comprising a DQS pad configured to receive a DQS signal, wherein the DQS pad comprises the feedback circuit.

8. The device of claim 7, wherein the feedback circuit comprises:
a third path comprising:
a fourth transistor comprising a fourth gate configured to receive the DQS signal; and
a fifth transistor comprising a fifth gate configured to receive an inverse signal of the DQS signal; and
a fourth path disposed in parallel with the third path, wherein the fourth path comprises a sixth transistor comprising a sixth gate configured to receive a reference voltage signal.

9. The device of claim 8, wherein the second path is coupled to a first node in the third path to receive the first compensation signal from the feedback circuit.

10. The device of claim 9, wherein the first path is coupled to a second node in the fourth path to receive the second compensation signal from the feedback circuit.

11. A device, comprising:
an amplifying device comprising:
a first amplifying stage configured to generate a first output signal and an inverse of the first output signal as a second output signal; and
a second amplifying stage coupled to the first amplifying stage, wherein the second amplifying stage comprises:
a first transistor comprising a first drain, a first gate coupled to the first amplifying stage to receive the first output signal, and a first source;
a first path coupled to the first source, wherein the second amplifying stage is configured to transmit a first amplified data signal along the first path;
a second transistor comprising a second drain, a second gate coupled to the first amplifying stage to receive the second output signal, and a second source; and
a second path coupled to the second source, wherein the second amplifying stage is configured to transmit a second amplified data signal as an inverse of the first amplified data signal along the second path; and
compensation circuitry coupled to the amplifying device via the first path and the second path, wherein the compensation circuitry when in operation calibrates the amplifying device by compensating a direct current (DC) bias of the amplifying device utilizing the first amplified data signal and the second amplified data signal.

12. The device of claim 11, comprising a data I/O signal (DQ) pad configured to receive a stream of data, wherein the DQ pad comprises the amplifying device and the compensation circuitry.

13. The device of claim 12, comprising a data strobe (DQS) pad configured to receive a DQS signal, wherein the DQS pad comprises a feedback circuit coupled to the compensation circuitry.

14. The device of claim 13, wherein the feedback circuit is configured to generate a third output signal and a fourth output signal as an inverse of the third output signal based upon the DQS signal and an inverse signal of the DQS signal.

15. The device of claim 14, wherein the compensation circuitry is configured to receive the third output signal and the fourth output signal from the feedback circuit and utilize the third output signal and the fourth output signal in calibrating the amplifying device.

16. A device, comprising:
an amplifying device comprising:
a first amplifying stage configured to generate a first output signal and an inverse of the first output signal as a second output signal; and
a second amplifying stage coupled to the first amplifying stage, wherein the second amplifying stage is configured to generate a first amplified data signal based upon the first output signal and a second amplified data signal based upon the second output signal;
compensation circuitry coupled to the amplifying device to receive the first amplified data signal and the second amplified data signal; and
feedback circuitry coupled to the compensation circuitry, wherein the feedback circuitry is configured to generate a third output signal and a fourth output signal as an inverse of the third output signal, wherein the compensation circuitry is configured to calibrates the amplifying device by compensating a direct current (DC) bias of the amplifying device utilizing the first amplified data signal, the second amplified data signal, the third output signal, and the fourth output signal.

17. The device of claim 16, wherein the feedback circuitry is configured to generate the third output signal and the fourth output signal based upon a data strobe (DQS) signal and a reference voltage signal.

18. The device of claim 17, wherein the first amplifying stage is configured to generate the first output signal and the second output signal based upon the reference voltage signal and a data I/O signal (DQ).

19. The device of claim 18, wherein the amplifying device is configured to generate a fifth output signal related to the first amplified data signal.

20. The device of claim 19, comprising a decision feedback equalizer (DFE) circuit coupled to the amplifying device, wherein the DFE is configured to receive the fifth output signal from the amplifying device as an input data signal.
